(19) United States
(12) Patent Application Publication
(10) Pub. No.: US 2023/0207624 A1
(43) Pub. Date: Jun. 29, 2023

(54) 3D VERTICAL NANO SHEET TRANSISTOR DESIGN USING SEMICONDUCTIVE OXIDES AND INSULATORS FOR NANO SHEET CORES

(71) Applicant: Tokyo Electron Limited, Tokyo (JP)

(72) Inventors: Mark I. GARDNER, Cedar Creek, TX (US); H. Jim Fulford, Marianna, FL (US); Partha Mukhopadhyay, Oviedo, FL (US)

(73) Assignee: Tokyo Electron Limited, Tokyo (JP)

(21) Appl. No.: 17/957,124

(22) Filed: Sep. 30, 2022

Related U.S. Application Data
(60) Provisional application No. 63/294,460, filed on Dec. 29, 2021.

(51) Int. Cl. H01L 29/06; H01L 29/417; H01L 29/423; H01L 29/786; H01L 21/8234

(52) U.S. Cl. CPC H01L 29/0673; H01L 29/41733; H01L 29/42392; H01L 29/78696; H01L 21/823412; H01L 21/823418

(57) ABSTRACT

A method of forming a vertical channel transistor includes forming a first source-drain (SD) contact on a semiconductor substrate, depositing a layer of vertical channel core material on the first SD contact and depositing a layer of second SD contact material on the layer of channel core material. Also included is pattern etching the layer of second SD contact material and the layer of channel core material to form a vertical channel core having a first end connected to the first SD contact and a second end opposite to the first end and connected to a second SD contact formed by the etching the layer of second SD contact material. A vertical channel structure is formed on a sidewall of the vertical channel core, and a gate-all-around (GAA) structure is formed to completely surrounding at least a portion of the vertical channel structure.

### INCORPORATION BY REFERENCE

This present disclosure claims the benefit of U.S. Provisional Application No. 63/294,460, titled 3D Vertical Nano Sheet Transistor Design Using Semiconductive Oxides and Insulators for Nano Sheet Cores filed on Dec. 29, 2021, which is incorporated herein by reference in its entirety.

### TECHNICAL FIELD

The present disclosure generally relates to microelectronic devices including semiconductor devices, transistors, and integrated circuits, including methods of microfabrication.

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire for three-dimensional (3D) semiconductor circuits in which transistors are stacked on top of each other.

3D integration, i.e. the vertical stacking of multiple devices, aims to overcome scaling limitations experienced in planar devices by increasing transistor density in volume rather than area. Although device stacking has been successfully demonstrated and implemented by the flash memory industry with the adoption of 3D NAND, application to random logic designs is substantially more difficult. 3D integration for logic chips (CPU (central processing unit), GPU (graphics processing unit), FPGA (field programmable gate array, SoC (System on a chip)) is being pursued.

### SUMMARY

The present disclosure is directed to forming one or more tiers of vertical channel transistors by various techniques including the following aspects of the present disclosure.

An aspect 1 provides a method of forming a vertical channel transistor. The method includes: forming a first source-drain (SD) contact on a semiconductor substrate; depositing a layer of vertical channel core material on the first SD contact; depositing a layer of second SD contact material on the layer of channel core material; pattern etching the layer of second SD contact material and the layer of channel core material to form a vertical channel core having a first end connected to the first SD contact and a second end opposite to the first end and connected to a second SD contact formed by the etching the layer of second SD contact material; forming a vertical channel structure on a sidewall of the vertical channel core; and forming a gate-all-around (GAA) structure completely surrounding at least a portion of the vertical channel structure at a position between the first SD contact and the second SD contact.

Aspect 2 includes the method of aspect 1, wherein the forming a first SD contact includes forming a conductive routing layer connected to the first SD contact.

Aspect 3 includes the method of aspect 1, wherein the depositing a layer of vertical channel core material include depositing at least one of a layer of dielectric core material and a layer of conductive oxide core material on the first SD contact.

Aspect 4 includes the method of aspect 1, wherein the forming a vertical channel structure on a sidewall of the vertical channel core includes forming a channel structure of 2D material on the sidewall of the vertical channel core.

Aspect 5 includes the method of aspect 1, wherein the forming a vertical channel structure on a sidewall of the vertical channel core includes forming a channel structure of conductive oxide material on the sidewall of the vertical channel core.

Aspect 6 includes the method of aspect 1, wherein the forming a gate-all-around (GAA) structure includes: forming a gate dielectric layer completely surrounding at least a portion of the vertical channel structure at a position between the first SD contact and the second SD contact; and forming a gate metal layer completely surrounding the gate dielectric layer.

Aspect 7 includes the method of aspect 6, wherein: the forming a gate dielectric layer includes performing atomic layer deposition (ALD) of the gate dielectric layer; and the forming a gate metal layer includes performing ALD of the gate metal layer.

Aspect 8 includes the method of aspect 7, further including directionally etching the gate metal layer to form the GAA structure.

Aspect 9 includes the method of aspect 1, further including: forming a first metal connection to the second SD contact; and forming a second metal connection to the GAA structure.

Aspect 10 includes the method of aspect 1, wherein the vertical channel transistor is a lower tier transistor formed in a formed in a lower tier of side-by-side vertical channel transistors.

Aspect 11 includes the method of aspect 10, further including forming an upper tier vertical channel transistor in an upper tier of side-by-side vertical channel transistors provided over the lower tier of transistors, wherein at least one upper tier vertical channel transistor is electrically connected to the lower tier transistor.

Aspect 12 includes the method of aspect 11, further including forming an interconnect layer between the lower tier and the upper tier of vertical channel transistors.

Aspect 13 includes the method of aspect 1, further including laterally etching a sidewall of the vertical channel core to form a recessed sidewall before the forming a vertical channel structure.

Aspect 14 includes the method of aspect 13, wherein the forming a vertical channel structure includes: depositing a conformal layer of conductive oxide material on the substrate to cover the recessed sidewall; and depositing a conformal layer of 2D material on the layer of conductive oxide material.

Aspect 15 includes the method of aspect 14, wherein the forming a vertical channel structure further includes directionally etching the layer of conductive oxide material and the layer of 2D material such that the vertical channel structure remains on the recessed sidewall of the vertical channel core.

Aspect 16 includes the method of aspect 14, wherein the forming a vertical channel structure further includes directionally etching the layer of conductive oxide material and the layer of 2D material such that the vertical channel structure remains on the recessed sidewall of the vertical channel core.

Aspect 17 provides a method of microfabrication. The method includes: forming a first wiring layer over a substrate, the first wiring layer including source-drain (SD) contact structures; forming a first dielectric layer over the first wiring layer; patterning and etching the first dielectric layer to form channel structures from the first dielectric layer, the first dielectric layer being etched until uncovering the first wiring layer; forming 2D material on sidewalls of the channel structures; depositing a second dielectric on the 2D material; and forming gate structures all around a cross section of the channel structures, the channel structures having a current flow direction perpendicular to the first metal wiring layer.

Aspect 18 includes the method of aspect 17, further including forming a second wiring layer over the channel structures having second SD contact structures.

Aspect 19 includes the method of aspect 18, wherein the channel structures and gate structures and SD contact structures define a first transistor plane of vertical channel transistors.

Aspect 20 includes the method of aspect 19, further including forming a second plane of vertical channel transistors over the first plane of vertical channel transistors.

### BRIEF DESCRIPTION OF THE DRAWINGS

Various embodiments of this disclosure that are proposed as examples will be described in detail with reference to the following figures, wherein like numerals reference like elements, and wherein:

FIGS. 1, 2, 3, 4, 5 and 6 are sectional views of intermediate structures in a process for manufacturing vertical channel transistors in accordance with an example embodiment of the disclosed invention;

FIG. 7 is a perspective view of a lower tier of side-by-side vertical channel transistors formed by the process of FIGS. 1-6;

FIGS. 8, 9 and 10, are sectional views of intermediate structures in a process for manufacturing an upper tier of vertical channel transistors in accordance with an example embodiment of the disclosed invention;

FIG. 11 illustrates tiers of vertical channel transistors in accordance with an example embodiment of the disclosed invention; and

FIG. 12 illustrates tiers of vertical channel transistors in accordance with another example embodiment of the disclosed invention.

### DETAILED DESCRIPTION OF EMBODIMENTS

As noted in the Background, 3D integration for logic chips, GPUs, FPGAs, and SoC for example is being pursued. The present inventors recognized that semiconductive materials that can be formed/deposited on a substrate without requiring a seed layer and/or at processing temperatures lower than 600 degrees Celsius are beneficial in forming vertical stacks or planes of transistors (e.g., 3D transistors). In contrast, semiconductors used to make conventional semiconductor devices are often formed by epitaxy, which requires a seed layer for growth. Requiring a seed layer can mean a need to uncover a particular material on a substrate that might be covered by many layers and structures. As appreciated by the present inventors, without needing to integrate access to a seed layer into a given fabrication flow, a semiconductive material can be easily formed over an existing plane of transistors to create an additional plane of transistors. Moreover, formation of conventional semiconductors can require high temperature deposition and annealing (e.g., greater than about 600 degrees Celsius). After initial high temperature processing, additional materials are added that may not tolerate high temperature processing. This means that if a first plane of transistors is formed, adding a second plane of transistors that needs high temperature processing can damage the first plane of transistors, leading to device failure. Accordingly, semiconductor materials that can be formed at less than 600 degrees Celsius are desirable. Without requiring a seed layer or high temperature processing, semiconductive materials herein can be formed on many different surfaces, easily integrate with various fabrication flows, and help enable vertical stacking of transistors.

Techniques disclosed herein may use alternative semiconductors in the microfabrication of semiconductor devices. Such semiconductors herein can be alternatives to silicon, germanium, gallium arsenide, and other commonly used semiconductors. Semiconductors and structures herein can include semiconductive oxides, semiconductive 2D materials, and semiconductive materials. This includes semiconductors (materials) that can be formed at relatively low temperatures and without epitaxy.

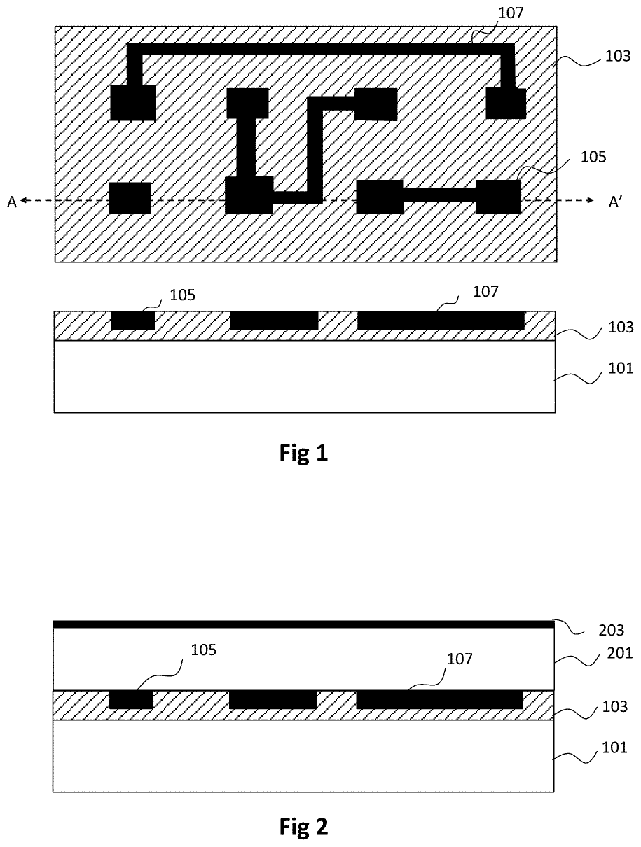

Several example embodiments using alternative semiconductive materials for implementing 3D integration are disclosed herein. FIGS. 1-6 illustrate intermediate structures in an example process flow for forming vertical channel transistors according to one embodiment of the disclosure. The example of FIGS. 1-6 includes a metal-first-layer design for fabricating transistors with 2D layers. Pre-aligned mask techniques provide for easy trench etching to fabricate the device. Further alignment offset of three different masks in the process can have little or no effect on device performance.

FIG. 1 shows top and cross-sectional views of an intermediate structure after formation of first source-drain (SD) contacts for vertical channel transistors. The cross-sectional view is provided in the plane A-A′ shown in the top view. The process begins by forming SD contacts on a Si (silicon) substrate. As shown in FIG. 1, the Si substrate includes Si layer 101, dielectric layer 103, SD contacts 105 and routing lines 107. This structure is formed by initially depositing dielectric 103 on Si layer 101 and using photolithography to pattern and etch pattern openings in the dielectric 103 for the SD contacts 105 and routing lines 107. In the embodiment of FIG. 1, pattern openings in the dielectric 103 are formed by etching the dielectric 103 approximately half way to the Si layer 101 to keep isolation between the Si and the conductive layer of SD contacts 105 and routing lines 107. After stripping photoresist, fill metal is deposited in the etch pattern openings to form the SD contacts 105 and metal routing lines 107, and CMP (planarize by chemical-mechanical polishing) is performed to remove metal overburden and provide the structure of FIG. 1. Any suitable metal or alternative conductive materials may be used to form the SD contacts 103 and metal routing lines 105.

The Si layer 101 may alternatively be made from semiconductor materials such as Ge, SiGe, GaAs, InAs, InP, semiconductive behaving oxide (e.g. In₂O₃, SnO₂, InGaZnO, and ZnO, SnO), 2D material (e.g. WS₂, WSe₂, WTe₂, MoS₂, MoSe₂, MoTe₂, HfS₂, ZrS₂, TiS₂, GaSe, InSe, phosphorene, HfSe₂, ZrSe₂, HfZrSe₂, etc.) or any other suitable semiconductor material in monocrystalline and/or polycrystalline form. Semiconductive behaving oxides and 2D materials may also be used for forming vertical channel structures as discussed further below.

Dielectric 201 is then deposited over the SD contact 105 and metal routing lines 107 as shown in FIG. 2. The dielectric 201 will be patterned to form a channel core for supporting device channels as discussed below. In the embodiment of FIG. 2, the dielectric 201 is different from the dielectric 103 however the same dielectric material may be used. As also shown in FIG. 2, a thin conductive layer such as metal layer 203 is deposited over the dielectric 201. The metal layer 203 will be used to form additional SD contacts.

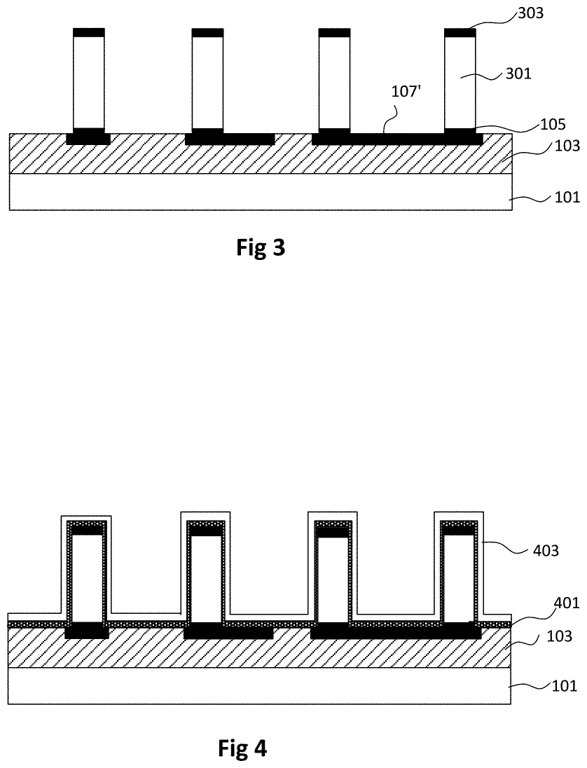

FIG. 3 shows vertical channel core structures and additional SD contacts. In forming this structure, a mask pattern is used to directionally etch the metal layer 203 and dielectric layer 201 to form the vertical channel cores 301 having a lower SD contact 105 and upper SD contact 303 at opposing ends of the core 301. These channel cores 301 may also be referred to as “mandrels”. In the embodiment of FIG. 3, the metal for SD contacts 105 and wiring lines 107 serves as an etch stop for the etch process forming the vertical channel cores. In the example shown, the etch timing is controlled such that the bottom metal layer is only slightly removed so that the wiring interconnect 107′ remains intact and functional. The present inventors recognized that such slight etching of metal routing lines has minimal effect on device performance. FIG. 3 shows the resulting structure after stripping off photoresist from the etch process.

Materials for the channel and gate dielectric are then deposited as shown in FIG. 4. In the example embodiment, atomic layer deposition (ALD) is used to deposit a conformal layer of 2D material layer 401 on the cores 301 which provide support structures for the vertical channel structures. Any suitable 2D material may be used. Also in the embodiment of FIG. 4, ALD is used to deposit a conformal layer of high-k dielectric 403 on the 2D layer 401. Any dielectric suitable for functioning as a gate dielectric may be used in place of the high-k dielectric 403.

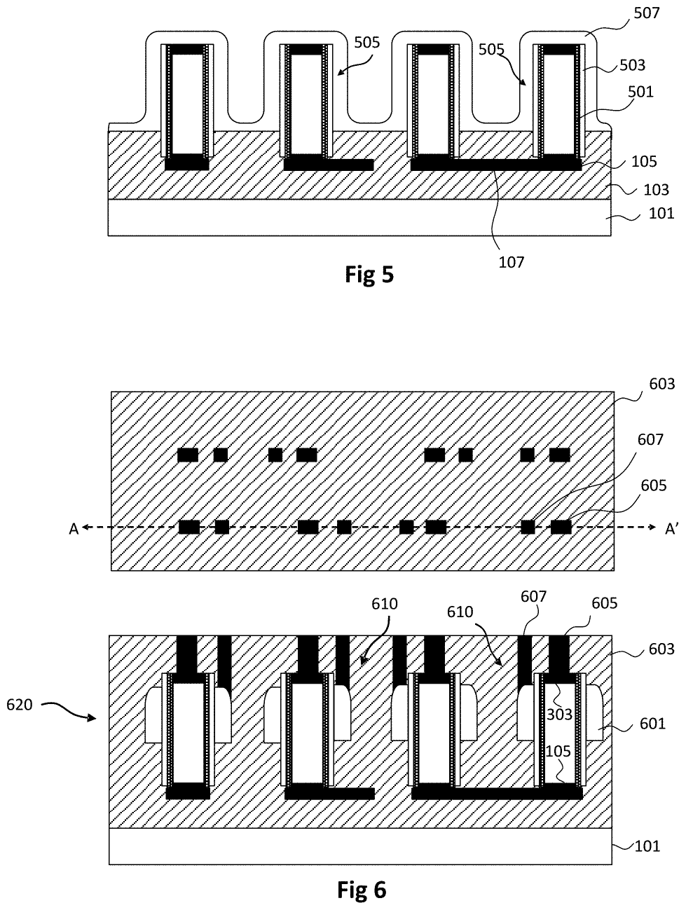

The vertical channel and gate dielectric structures are then formed, followed by depositing gate metal material as shown in FIG. 5. In forming this structure, the high-k layer 403 and 2D channel material 401 are directionally etched to form vertical channel structure 501 and gate dielectric structure 503 which remain as sidewall structure 505 on a sidewall of the dielectric core 301. By this process, the 2D material of the channel structure 501 is protected on the side wall of core 301 by the high-k material of the gate dielectric structure 503. After forming the sidewall structures 505, regrowth of another dielectric selective to dielectric 103 is performed to protect the bottom SD regions. The same dielectric material 103 is shown in FIG. 5, but different dielectrics may be used. ALD is then used to deposit a conformal gate metal layer 507 as shown in FIG. 5. The SD contacts 105 and 303 may be formed of any conductive material suitable for use with 2D channel materials.

The gate-all-around (GAA) structure is then formed for the vertical transistors, and SD and GAA connections are formed as shown in FIG. 6. The GAA structure of this example may be formed by directionally etching the gate metal layer 507 to clear the top part of the channel cores 301 and vertical channels 501 for SD connections. The directional etch also removes metal 507 in regions between vertical cores 301 to form GAA structures 601 and provide isolation of adjacent devices. This completes each of the vertical channel transistors 610 to form a plane or tier 620 of side-by-side vertical channel transistors 610.

The transistor connections are then formed by depositing a dielectric 603 over the substrate and performing photolithography and directional etching of the dielectric 603 to form pattern openings which are then filled with conductive material such as metal to provide SD connections 605 and GAA connections 607. Etch of dielectric 603 is performed with etch stop on the metal SD contact metal 303 and GAA metal 601. After stripping of photoresist, fill metal is deposited in the openings and CMP is performed to form SD connection 605 and GAA connection 607 as shown in FIG. 6. The routing design for SD connection 605 and GAA connection 607 provides one example for illustration only, and other routing designs may be used. Any metal (e.g., different work function) can be used for SD contacts 303 and gate metal 601 based on the application.

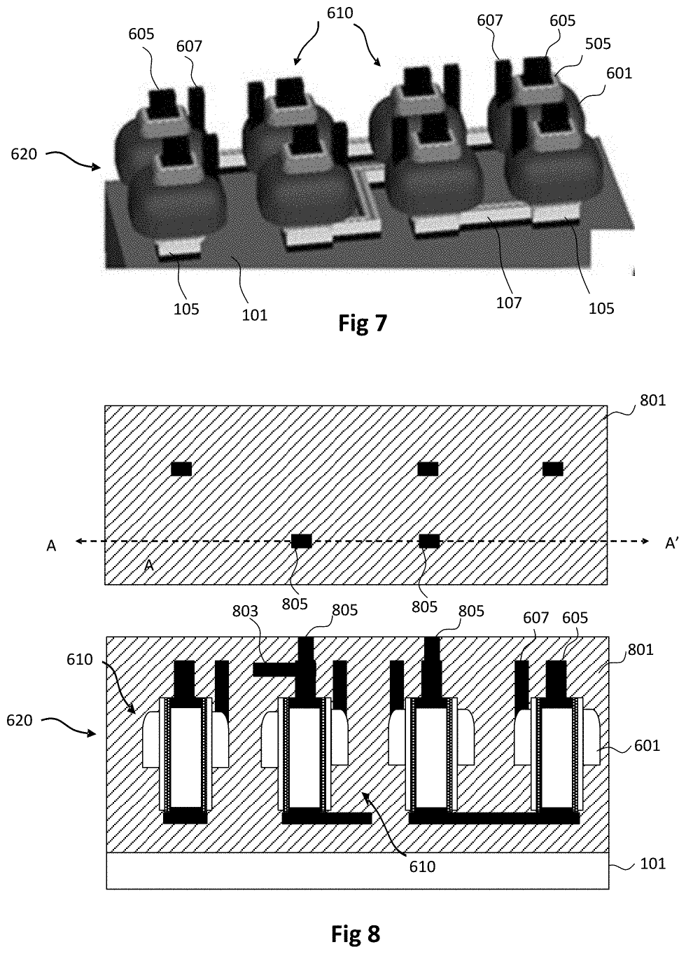

FIG. 7 is a simulated perspective view of a lower tier of side-by-side vertical channel transistors. Surrounding dielectric is removed to reveal the structure of the side-by-side transistors 610 in the lower tier 620.

Insulation and/or dielectric layers in the process of FIGS. 1-6 may be implemented by any suitable dielectric material such as SiO, SiN, SiON, SiC, SiOC, SiCN, SiOCN, the like, or a combination thereof. Dielectric structures may also be implemented as high-k dielectrics. The same or different dielectric materials can be used for different process steps and structures described in FIGS. 1-6. Device contacts, connections, vias and the like may be made of any conductive material, such as a doped polysilicon material or a metal such as W, Co, Ru, Cu, Al, the like, or combinations thereof. The same or different conductor materials can be used for the process steps and structures of FIGS. 1-6.

The example embodiment of FIGS. 1-6 provides transistor channels which include a 2D material. Some example 2D materials for use in forming a channel include, but are not limited to, WS₂, WSe₂, WTe₂, MoS₂, MoSe₂, MoTe₂, HfS₂, ZrS₂, TiS₂, GaSe, InSe, phosphorene, and other similar materials. A “semiconductive 2D material” herein is a 2D material with semiconductor properties. The 2D materials described herein may be deposited by, for example, an atomic layer deposition (ALD) process and may be 5-15 angstroms thick, the thinness lending to their name-2D material. Other deposition techniques may also be used, including, but not limited to, chemical vapor deposition (CVD), physical vapor deposition (PVD), and plasma-enhanced deposition techniques. The materials may be annealed during or after the device formation process to recrystallize or grow the crystals and thereby improve electrical characteristics. Thus forming a semiconductive material can include deposition and annealing. A “semiconductive material” herein can be any material with semiconductor properties. Such materials can include elements or compounds normally associated with dielectrics. Such materials can include compounds formed without requiring a seed layer, and can be formed at temperatures lower than about 500-600 degrees Celsius.

Alternatively, other semiconductive materials may be used. Semiconductive materials herein may have properties similar to elemental semiconductor materials, and can be used to fabricate vertical stacks or planes of transistors. Note that given transistors within the vertical stacks can have channels with horizontal or vertical orientation relative to a working surface of the substrate. Certain materials, when combined with oxygen, may form new materials that exhibit semiconductor properties. For example, these semiconductor materials can turn “off” with low off-state leakage current or can become highly conductive under certain circumstances. In other words, such materials have an electrical conductivity value falling between an electrical conductor and an electrical insulator. Some examples of N-type semiconductive materials for channels include In₂O₃, SnO₂, InGaZnO, and ZnO. One example of a P-type semiconductive material for channels is SnO. Thus, a “semiconductive oxide” herein is an oxygen-containing material having semiconductor properties.

In some embodiments, the dielectric core 301 may be replaced with a conductive oxide core. By using a 3D Mandrel or 3D Nano sheet Core made of either Oxide or an Oxide Semiconductor enables both semiconductive oxides channels and 2D channels and combinations to be realized for this disclosure. 2D Materials have greatly enhanced mobility relative to single crystal silicon. Conductive oxides may be used with both a solid core 3D Nano sheet core or an insulative core with a conductive oxide (semiconductive oxide) shell as options. Techniques herein enable all forms of growth and deposition of both 2D materials and conductive oxides. Embodiments can also include using a channel of both 2D Material and conductive oxide on the same 3D device. Techniques herein enable many 3D devices to be stacked n transistors tall. Replacing the dielectric core with conductive oxide enables different polarity conductive oxide to be matched with 2D channel polarity. The benefit of this structural design allows use of any dielectric, semiconductive or non-conductive as a channel core with little change to the fabrication process steps. Further, parallel conduction is provided with a 2D channel as well as conductive oxide channel.

FIGS. 8-10 illustrate intermediate structures in an example process flow for forming an additional tier of vertical channel transistors according to one embodiment of the disclosure. FIG. 8 shows a structure after formation of an interconnect routing layer and vias for connecting a lower tier of transistors to an upper tier of transistors. The structure is formed by first depositing additional dielectric 801 on the first tier of devices to provide isolation between stacks. The dielectric 801 is patterned using an interconnect routing mask with etch stop on metal of the SD contacts of the lower tier. Fill metal is deposited in the openings and CMP is performed to form interconnects such as wiring structure 803 shown in FIG. 8. This routing layer allows to connect SDs and gates to the outer pads of the device, as well as to interconnect with other transistors as per circuit design requirement. Additional dielectric is then deposited on the interconnect layer and patterned and etched using a via pattern mask. Conductive material is de[posited within openings of the via mask and CMP is performed to form vias 805 as shown in FIG. 8. The via layer will connect the SD contacts and/or gates of the lower tier to the top hierarchy transistors.

FIG. 9 shows a structure after forming the lower SD contacts and metal routing layer of the upper tier as well as the channel structures and initial gate metal of the transistors in the upper tier. The process is similar to that described in FIGS. 1-5 and includes depositing a dielectric layer 901 on the vias 805, and patterning and filling the pattern with conductive material for the routing lines 903 and SD contacts 905. The mask pattern for the upper tier is shown as being the same as for the lower tier for demonstration purposes. Channel cores 907 and upper SD contacts 909 of the upper transistors are then formed by etching as previously described, and channel structures and gate dielectric structures are formed as sidewall structures 911. The substrate is then covered with the gate metal 913 to provide the structure of FIG. 9. Where the 2D material of the upper tier has different polarity from the 2D material of the lower tier transistors, conductive materials for the SD contacts and gate connection may also be different among the two tiers.

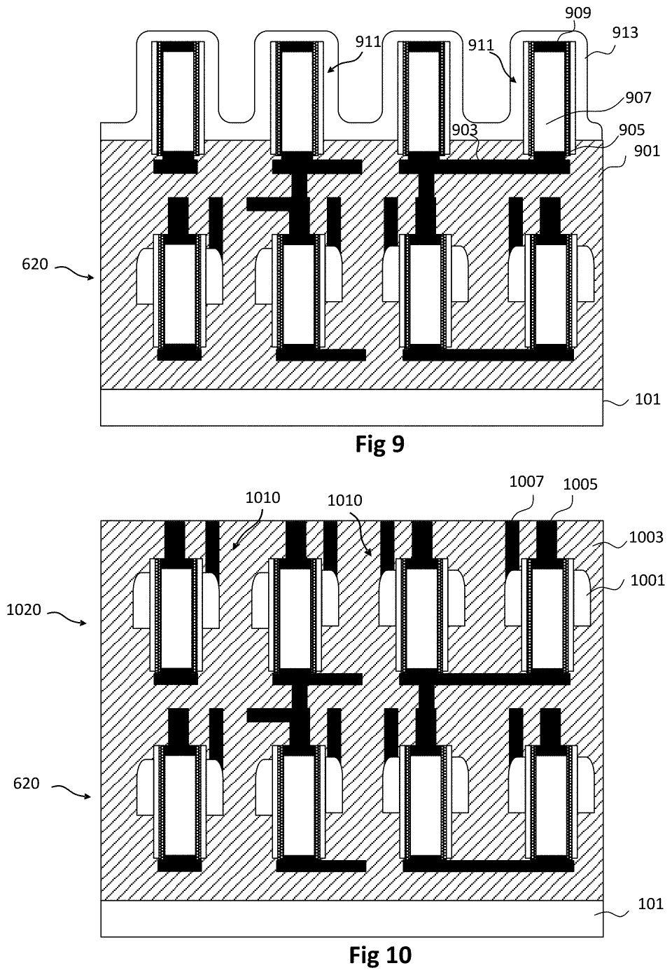

FIG. 10 shows a structure after formation of the GAA structure, SD connections and GAA connections in the upper tier of transistors. Process steps are similar to those described in FIG. 6 and includes directionally etching the gate metal layer 913 to clear the top part of the channel cores 907 for SD connections and to form GAA structures 1001. This completes each of the vertical channel transistors 1010 to form an upper plane or tier 1020 of side-by-side vertical channel transistors. The transistor connections are then formed by depositing a dielectric 1003 over the substrate and performing photolithography and directional etching of the dielectric 1003 to form pattern openings which are then filled with conductive material such as metal to provide SD connections 1005 and GAA connections 1007. Gate conductive material and gate dielectric material of the upper tier can be different than the materials of the lower tier. For example, gate metal and or/SD contact metal may be based on the polarity of 2D material used in the upper tier.

Additional tiers of transistors may be formed on the tier 1020 using similar process steps. For example, n-number of transistors in a stack may have the same or different 2D channel materials with a dielectric nanosheet core. Polarity of the 2D channels in a stack can be varied as p-type or n-type. Different High-k, gate metal, and SD metal can be used for different tiers of transistors, for example. Further, n number of transistor in a stack may have the same or different 2D channel materials with the same or different conductive oxide nanosheets. Polarity of the 2D transistors in the stack and semiconductive oxide may be paired for p-type or n-type transistors. Parallel channel vertical nanosheets of 2D and semiconductive oxide may also be provided in accordance with the teachings of this disclosure. As another example, n number of stacks of the same or different conductive oxide with the same dielectric nanosheet may be implemented. Still further, n number of transistors in a stack may have the same or different 2D channels with the same or different conductive oxide nanosheets on a dielectric core (this results in a conductive oxide channel shell over an insulative core 3D Nano Sheet)

Additional feature of techniques herein provide for using one unit cell to make both side-by-side and CFET (NMOS over PMOS) using just one unit cell. Techniques here enable high performance CMOS with very robust manufacturing because very few process steps are needed. Embodiments can have n devices tall with both CFET and side-by-side transistor architectures. Additional features include a metal first integration with all of embodiment flows.

In some embodiments, core structures may be recessed to provide for more area of connection of conductive oxide to metal. FIG. 11 illustrates a cross section of a structure implementing vertical channels transistors having a recessed core. As seen, substrate 1101 includes two tiers 1120 and 1130 of vertical transistors thereon. Each of the vertical channel transistors includes a core 1105 with lower SD contact 1107 and upper SD contact 1109 on opposing ends of the core 1105. In the embodiment of FIG. 11, the cores 1105 are dielectric, but conductive oxides may be used. As shown, the cores 1105 are laterally recessed with respect to the SD contacts 1107 and 1109. In some embodiments, the lateral recess is formed by selective etch processing. ALD deposition of conductive oxide is performed to cover the substrate followed by a directional etch of the conductive oxide to form the conductive oxide sidewall structure 1111. Similarly, ALD deposition of high-k material is performed to cover the substrate followed by a directional etch of the high-k material to form the high-k sidewall structure 1113. GAA structures 1115 are formed to complete the vertical transistors 1117 and transistor connections are formed as previously described herein.

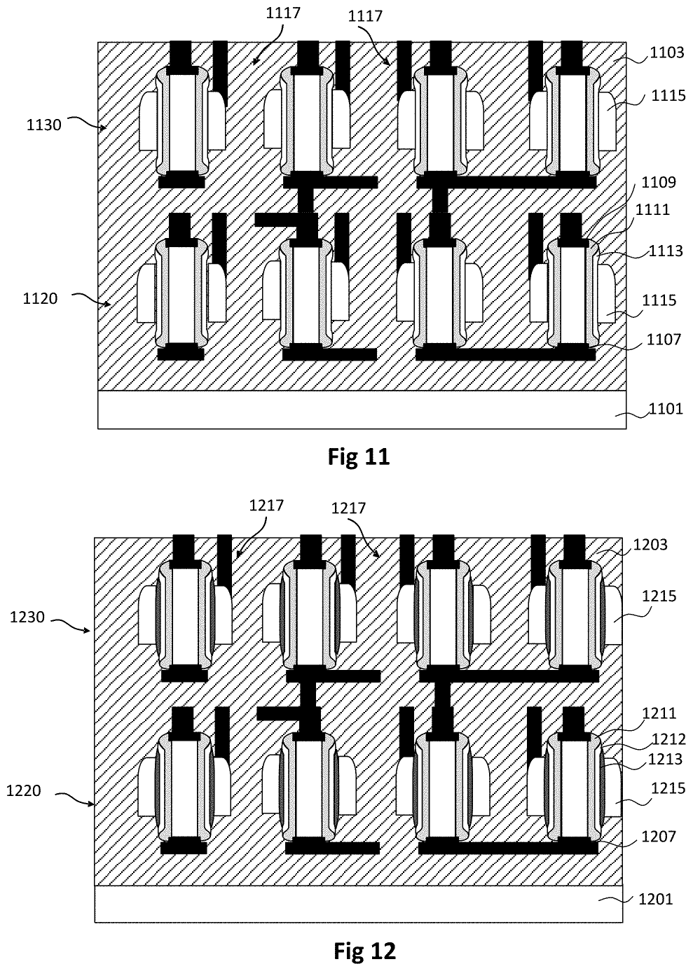

FIG. 12 illustrates a cross section of a structure implementing vertical channels transistors having a recessed core. As seen, substrate 1201 includes two tiers 1220 and 1230 of vertical transistors thereon. Each of the vertical channel transistors includes a recessed core 1205 with lower SD contact 1207 and upper SD contact 1209 on opposing ends of the core 1205. As shown in FIG. 12, dielectric remains as a core while conductive oxide 1211 and 2D material 1212 are wrapped on core 1205 to provide parallel channel, followed by gate oxide 1213. Two different polarities of conductive oxide may be matched with the polarity of 2D materials. One benefit of this structural design allows use of any dielectric, conductive or non-conductive as core without changing the fabrication steps much. Further, parallel conduction with 2D channel as well as conductive oxide channel is provided.

ALD deposition of conductive oxide is performed to cover the substrate followed by a directional etch of the conductive oxide to form the conductive oxide sidewall structure 1111. Similarly, ALD deposition of high-k material is performed to cover the substrate followed by a directional etch of the high-k material to form the high-k sidewall structure 1113. GAA structures 1115 are formed to complete the vertical transistors 1117 and transistor connections are formed as previously described herein.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Of course, the order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

What is claimed is:

1. A method of forming a vertical channel transistor, including:
forming a first source-drain (SD) contact on a semiconductor substrate;
depositing a layer of vertical channel core material on the first SD contact;
depositing a layer of second SD contact material on the layer of channel core material;
pattern etching the layer of second SD contact material and the layer of channel core material to form a vertical channel core having a first end connected to the first SD contact and a second end opposite to the first end and connected to a second SD contact formed by the etching the layer of second SD contact material;
forming a vertical channel structure on a sidewall of the vertical channel core; and
forming a gate-all-around (GAA) structure completely surrounding at least a portion of the vertical channel structure at a position between the first SD contact and the second SD contact.

2. The method of claim 1, wherein the forming a first SD contact includes forming a conductive routing layer connected to the first SD contact.

3. The method of claim 1, wherein the depositing a layer of vertical channel core material include depositing at least one of a layer of dielectric core material and a layer of conductive oxide core material on the first SD contact.

4. The method of claim 1, wherein the forming a vertical channel structure on a sidewall of the vertical channel core includes forming a channel structure of 2D material on the sidewall of the vertical channel core.

5. The method of claim 1, wherein the forming a vertical channel structure on a sidewall of the vertical channel core includes forming a channel structure of conductive oxide material on the sidewall of the vertical channel core.

6. The method of claim 1, wherein the forming a gate-all-around (GAA) structure includes:
forming a gate dielectric layer completely surrounding at least a portion of the vertical channel structure at a position between the first SD contact and the second SD contact; and
forming a gate metal layer completely surrounding the gate dielectric layer.

7. The method of claim 6, wherein:
the forming a gate dielectric layer includes performing atomic layer deposition (ALD) of the gate dielectric layer; and
the forming a gate metal layer includes performing ALD of the gate metal layer.

8. The method of claim 7, further including directionally etching the gate metal layer to form the GAA structure.

9. The method of claim 1, further including:
forming a first metal connection to the second SD contact; and
forming a second metal connection to the GAA structure.

10. The method of claim 1, wherein the vertical channel transistor is a lower tier transistor formed in a formed in a lower tier of side-by-side vertical channel transistors.

11. The method of claim 10, further including forming an upper tier vertical channel transistor in an upper tier of side-by-side vertical channel transistors provided over the lower tier of transistors, wherein at least one upper tier vertical channel transistor is electrically connected to the lower tier transistor.

12. The method of claim 11, further including forming an interconnect layer between the lower tier and the upper tier of vertical channel transistors.

13. The method of claim 1, further including laterally etching a sidewall of the vertical channel core to form a recessed sidewall before the forming a vertical channel structure.

14. The method of claim 13, wherein the forming a vertical channel structure includes:
depositing a conformal layer of conductive oxide material on the substrate to cover the recessed sidewall; and
depositing a conformal layer of 2D material on the layer of conductive oxide material.

15. The method of claim 14, wherein the forming a vertical channel structure further includes directionally etching the layer of conductive oxide material and the layer of 2D material such that the vertical channel structure remains on the recessed sidewall of the vertical channel core.

16. The method of claim 14, further including forming the gate-all-around (GAA) structure completely surrounding at least a portion of the vertical channel structure remaining on the recessed sidewall of the vertical channel core.

17. A method of microfabrication, the method including:
forming a first wiring layer over a substrate, the first wiring layer including source-drain (SD) contact structures;
forming a first dielectric layer over the first wiring layer;
patterning and etching the first dielectric layer to form channel structures from the first dielectric layer, the first dielectric layer being etched until uncovering the first wiring layer;
forming 2D material on sidewalls of the channel structures;
depositing a second dielectric on the 2D material; and
forming gate structures all around a cross section of the channel structures, the channel structures having a current flow direction perpendicular to the first metal wiring layer.

18. The method of claim 17, further including forming a second wiring layer over the channel structures having second SD contact structures.

19. The method of claim 18, wherein the channel structures and gate structures and SD contact structures define a first transistor plane of vertical channel transistors.

20. The method of claim 19, further including forming a second plane of vertical channel transistors over the first plane of vertical channel transistors.
